(19) United States
(12) Patent Application Publication
(10) Pub. No.: US 2013/0247954 A1
(43) Pub. Date: Sep. 26, 2013

(54) Window or Door Having a Photovoltaic Module

(71) Applicant: SMA SOLAR TECHNOLOGY AG, Niestetal (DE)

(72) Inventor: Veit-Dominik Kunz, Kassel (DE)

(73) Assignee: SMA Solar Technology AG, Niestetal (DE)

(21) Appl. No.: 13/869,450

(22) Filed: Apr. 24, 2013

Related U.S. Application Data
(63) Continuation of application No. PCT/EP2011/068884, filed on Oct. 27, 2011.

(30) Foreign Application Priority Data
Oct. 29, 2010 (DE) 202010014775.1

(51) Int. Cl. H01L 31/042

(52) U.S. Cl. CPC H01L 31/0422
USPC 136/244

(57) ABSTRACT

A window or door for a building has a glass element surrounded by a frame or a fixed frame and comprises at least one PV module. At least one electrical or electronic component for operating the at least one PV module is arranged in the frame or in the fixed frame.

### REFERENCE TO RELATED APPLICATIONS

This application is a continuation application of International Patent Application No. PCT/EP2011/068884, filed on Oct. 27, 2011, which claims priority to German Patent Application No. 20 2010 014 775.1, filed on Oct. 29, 2010, the contents of which are incorporated by reference in their entirety.

### FIELD

The disclosure relates to a window or a door for a building, wherein a glass element is surrounded by a frame or a fixed frame and has at least one photovoltaic module. The window can be designed with a pivotable frame or as a fixed window, the glass element of this fixed window being held only by a fixed frame in a building opening.

### BACKGROUND

The arrangement of photovoltaic modules, abbreviated to PV modules in the text which follows, in a window frame and the arrangement of PV modules on or in the glass element of a window is known from the prior art. For example, EP 1 529 922 A2 discloses, in the case of an insulating glass pane having at least two panes of glass which are held by a spacer frame, arranging PV modules within the intermediate space which is formed by the panes of glass, wherein these PV modules can also be arranged on the inner face of one of the two panes of glass. The electrical energy which is generated by the PV modules is routed to the outside by separate plugs in this case. EP 0 028 820 A2 describes a similar construction where solar cells are accommodated in the hollow space between glazed window or facade parts.

DE 10 2009 004 995 A1 likewise describes a PV module as part of a window, wherein the PV module is designed such that it is pivotable for optimum adjustment with respect to the sun.

EP 1 703 063 A1 relates to providing what is called an autonomous window. Specifically, the document relates to a window with which electrical energy can be supplied to an adjoining load, for example a roller shutter or the blind of a window of this kind. For the purpose of supplying electrical energy, a PV module is arranged on the frame of the window, wherein switching, open-loop and closed-loop control elements which are required for operating the photovoltaic module are intended to be arranged in a hollow chamber in the frame of the window. The document likewise discloses selectively arranging the PV module in the region of the glazing bar of the glass element of the window for the purpose of arranging the PV modules on the frame of the window. The aim of the teaching of this citation is for PV modules to provide a relatively small amount of energy; the energy, however, having to be of such a magnitude that it can be used, for example, to operate a blind of a window.

PV modules in the form of a transparent solar window are known from DE 10010257 A. Conventional windows can be replaced by solar windows of this kind without significant losses with respect to the transmission of light being expected.

U.S. 2003/0098056 A1 discloses a design of a window construction in which, instead of a window pane, an insert element comprising PV modules is held by the window frame, wherein the insert element additionally also holds electrical and electronic components such as, for example, inverters and battery modules which are connected to the photovoltaic cells. The insert element which is inserted into the window frame therefore encloses the electrical or electronic components in the same way as the PV modules in this case. One disadvantage of this is, among others, the visual appearance of a window of this kind, in particular when the PV modules are substantially transparent, and inasmuch as the individual electrical components remain visible behind the PV modules. Furthermore, it cannot be denied that the arrangement of the electrical or electronic components for operating the PV modules at such a specific point in the window can lead to impermissible heating of the components caused by solar irradiation.

### SUMMARY

The disclosure provides a window or a door with which electrical energy can be generated, wherein the electrical energy is not only to be used for operating electrical system parts which are directly related to the window, for example blinds, but also in excess of this for being possibly fed into a public or private supply system (power supply grid). Equally, it is to be ensured that the visual impression of a window itself, and therefore also of the building as such, is not adversely affected or is only slightly adversely affected by the installation of a photovoltaic system of this kind.

The disclosure arranges at least one electrical or electronic component for operating the PV module in the frame of the glass element of the window or the door and/or in the fixed frame of the window or door leaf. It is clear from this that, when a substantially transparent PV module is used, with the electrical and electronic components required for operating the PV module being arranged within the frame of the glass element or within the fixed frame of the window or door leaf, the visual appearance of a building which is equipped with a PV module of this kind is only slightly adversely affected, if at all. Advantages of arranging the component or components in the frame or the fixed frame can be found in low mechanical loading on the components as a result of vibrations and good heat dissipation.

Specifically, in one embodiment the electrical or electronic components can be a module inverter, a submodule inverter, a DC/DC actuator, a DC/AC converter, an MPP (Maximum Power Point) tracker, a communication unit, an energy storage means, for example a battery, and the like. A plurality of the abovementioned components may possibly also be accommodated in the frame of the glass element or in the fixed frame of the window or door leaf.

According to a further embodiment of the disclosure, the frame or the fixed frame has at least one chamber in order to hold the corresponding components. This chamber can be closed in one embodiment, specifically by the component itself, the housing of the component or particularly advantageously by a cover which can be removed from the chamber, wherein the cover can be designed such that it can be clipped into or mounted onto the profile of the frame. This has the advantage of a high degree of serviceability since, for example when the window is open and the components are arranged in the frame, the component is directly accessible after the cover is removed.

According to a further embodiment of the disclosure, the frame or the fixed frame can be designed as a hollow profile, wherein the chamber for holding the electrical or electronic components is a constituent part of the profiling of the hollow profile. The electrical or electronic component can have a housing which can be inserted into the chamber in the frame. A modular design of this kind provides an excellent degree of serviceability, particularly with respect to the ability to replace the parts, for example in the event of a defect.

An embodiment of this kind is particularly easy to service and install when the component and/or the housing have/has a plug module, wherein a corresponding plug module is provided in the chamber, wherein the two plug modules make contact with one another when the housing or the electrical and electronic component is inserted into the chamber. The electrical component can also be an energy storage means in this respect.

According to a further embodiment, the housing for holding the electrical and electronic components can have cooling ribs in order to assist in dissipating the heat which is produced during operation to the outside. An embodiment of this kind of the housing is expedient when the housing for holding the electrical or electronic component is not contacting the wall of the frame or of the fixed frame with the entire surface of its outer wall directly such that the heat may not be emitted directly through the frame or profile wall.

The frame of the glass element, for example of a window leaf, may be designed as a hollow profile in cross section, such that the individual chambers of the frame are connected to one another and form a continuous chamber, this being the case particularly when the individual frame elements are mitered. The advantage of this is that the heat which is generated by the electrical or electronic components is distributed uniformly in the frame and therefore a considerable surface area and volume is available for heat dissipation. This is the case particularly when the frame of the window is produced from metal, in particular from aluminum or an aluminum alloy. This is because metal generally has good thermal conduction properties, and in this respect the heat which is generated within the frame can be emitted to the outside via the profile of the window frame. The above statements apply in the same way to the arrangement of the components in the fixed frame too.

According to a further embodiment of the disclosure, a cutout or a window for reading off a display can be arranged in the region of the electrical or electronic component in order to read off a status indictor of an electrical or electronic component. In addition, switches on the electrical or electronic component can be operated through a cutout of this kind.

The electrical energy which is generated by the at least one PV module which is arranged in or on the glass element has to be diverted in one embodiment. The PV modules are electrically connected to the electronic and electrical components which are accommodated, for example, in the frame of the glass element or else in the fixed frame of the window leaf or of the door leaf. In each case, the energy is routed from the window or door leaf to the fixed frame or a circumjacent masonry. In the simplest case, this diverting of the electric energy is performed using a cable which is routed in the transition from the leaf to the fixed frame. In this case, the cable can have a flexible conduit for protection purposes. In this case, the flexible conduit prevents the cable from being damaged when the cable is bent when the window or the door is opened and closed.

According to another embodiment, the hinge can be designed in such a way that the cable is routed through the hinge. That is to say, the cable is inserted laterally into the bushing and is routed out centrally through the pin, wherein the pin holds the bushing.

However, a particularly advantageous embodiment for routing energy in the region of the hinge is characterized by the electrical energy being conducted directly through at least one hinge, wherein the hinge is electrically insulated at its outer circumference. A hinge which has a pin and a bushing which holds the pin can route the electrical energy from the leaf to cables in the masonry of the building via the hinge. It should be noted here that both the bushing and the pin are composed of metal and are therefore electroconductive in one embodiment.

Regarding the transmitting of electrical energy through the hinge, according to a further embodiment the pin can be subdivided into at least two sections by at least one electrical insulation means. In this case, the electrical insulation means can be designed in the manner of a cap, wherein, in a corresponding manner, the bushing has at least two electroconductive elements, for example in the form of a ring or a sleeve, which are arranged in the bushing in an electrically insulated manner and which are connected to the electrical or electronic components by cables. The two sections of the pin are also finally connected to the cables for conducting the electrical energy. A bushing of this kind, in which at least two electroconductive sections are formed by an electrical insulation means, provides the option of transmitting in each case two potentials, specifically the positive (DC+) and negative (DC−) DC voltage potential, in each case with ground (GND), for the purpose of supplying power in the case of two hinges. This has the advantage that both DC+ and DC− are inherently shielded and the hinge does not have to be separately insulated from the frame and fixed frame. If the pins and bushing are of integral design, as described above, it is necessary to route DC+ and DC− via the hinge in each case in order to form the electrical circuit. It is also possible to transmit DC+ and DC− via an individual two-pole hinge which is constructed in this way and is insulated from the frame.

On account of the separation into DC+ and DC− and GND, the solar modules and therefore the components have a different potential to GND, particularly in the case of a series circuit comprising the output lines of a plurality of windows and/or doors according to the disclosure, wherein in each case only the safe potential of the connected solar module drops across one of the components.

It goes without saying that it is possible, in principle, to subdivide the pin into more than two sections by virtue of the arrangement of a plurality of caps as electrical insulation means. In this case, it is then not only possible to transmit DC+ and DC− but furthermore there is the option to lead further electrical signals out of the window or door leaf.

The use of the hinge as a coupling for transmitting the electrical energy between the leaf and fixed frame is substantially free of wear and insusceptible to faults.

According to a further embodiment of the disclosure, the hinge and/or the door or window frame, which is produced from metal, can be designed as an antenna in order to transmit data from and to the communication unit in the frame.

It is also feasible to design the housing of an electrical or electronic component itself as a hinge, in particular to integrate the component directly in the pin of the hinge.

It is also possible, in principle, to fit an electrical or electronic component to the hinge; in this case, it can be arranged both on the side of the hinge and beneath the hinge, wherein the two hinges form a bar-like unit, with the electrical or electronic component between the hinges in the bar-like unit. The advantage of this is short cable runs and therefore lower losses.

According to a further embodiment of the disclosure, the door or window handle, as a fitting part, can be connected to one or more of the electrical or electronic components, wherein a photovoltaic system which comprises the at least one PV module can be disconnected from the supply grid, for example, by pivoting the handle.

According to another embodiment of the disclosure, the handle has at least one switch, the switch being connected to the electrical or electronic component. That is to say, the handle not only fulfills its function as a window or door handle but, if it has further switches, these switches are also used to control the electrical or electronic components.

### BRIEF DESCRIPTION OF THE DRAWINGS

The disclosure will be explained in greater detail by way of example below with reference to the drawings, in which

FIG. 1a shows a front view of a window;

FIG. 1b shows a sectional view of the design of a hinge for holding the window leaf in the fixed frame;

FIG. 2 shows a sectional view of the hollow profile of the frame of a glass element, wherein the pane of window glass which is held by the profile is visible;

FIG. 3 shows the housing for holding an electrical or electronic component to be held by the hollow profile;

FIG. 4 shows an electronic component having a plug module to be held by the chamber in the frame of the glass element;

FIG. 5 schematically shows the arrangement of an electrical or electronic component in the fixed frame;

FIG. 6 shows an embodiment of a hinge with two sections of the pin which are insulated from one another;

FIG. 7 shows a further embodiment of a hinge, wherein the cable is routed through the hinge;

FIG. 8 shows a further embodiment of a hinge, wherein the electrical or electronic component is arranged in the hinge;

FIG. 9a shows an embodiment in which the electrical or electronic component is accommodated beneath the hinge in the extended hinge body;

FIG. 9b shows an further embodiment similar to FIG. 9a, wherein the electronic component is arranged in a housing which connects the two hinges;

FIG. 10 shows a handle having a switch for controlling a component.

### DETAILED DESCRIPTION

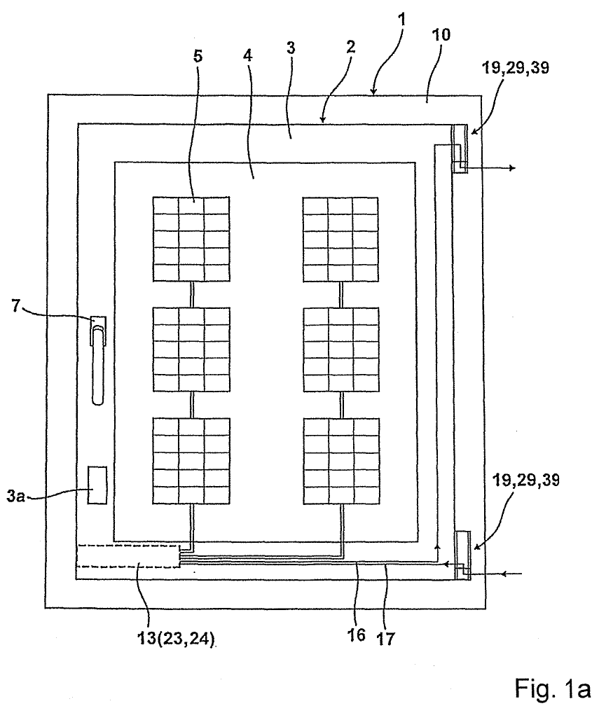

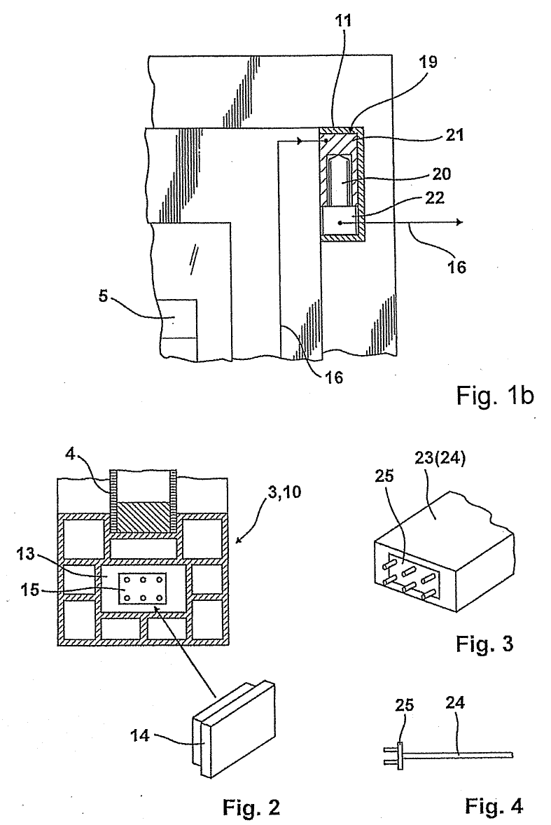

Referring to FIG. 1a, a window 1 comprises a window leaf 2, wherein the window leaf 2 has a circumferential frame 3 which holds a pane 4 of window glass on which individual PV modules 5 are mounted. The frame of the leaf 2 also has a handle 7. The leaf 2 is connected to a fixed frame 10 by hinges 19, 29, 39.

A chamber 13 that is used to hold a housing 23 in FIG. 3 can be seen in the frame 3 which, as shown in the sectional view according to FIG. 2, is designed as a hollow profile, wherein the housing 23 holds one or more electrical or electronic components 24, without this being illustrated in any detail. The chamber 13 can be closed by a cover 14 which advantageously can be clipped into the chamber or can be plug-mounted or screwed onto the chamber. The frame 3 also has an inspection window 3a in order to be able to read off, for example, a display of the electrical or electronic component 24 or else to allow access to switching options on the electrical or electronic component 24.

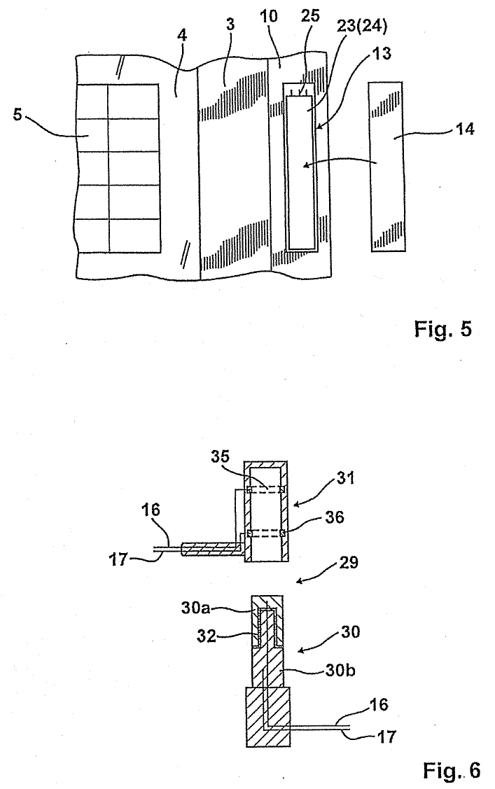

The housing 23 has, at its end face, a male plug module 25 that corresponds to a corresponding female plug module 15 in the end face of the chamber 13. An electrical or electronic component 24 with its own plug module 25 can selectively also be held by the chamber 13 (FIG. 4). As an alternative or in addition, a chamber 13 that can be fitted with a corresponding electrical or electronic component 24 can be provided in the fixed frame 10 (FIG. 5).

As shown in FIG. 1a, the connection to the PV modules 5 is established by means of the plug modules 15, 25 and, furthermore, the electrical energy is diverted by means of the hinges 19, 29, 39, for example to the supply system, via corresponding cables 16, 17.

FIG. 1b shows the connection of the cable 16 to an electroconductive bushing 21 of the hinge 19 and the electrical connection of the bushing to a pin 20. A cable 16 starts at a base 22 of the pin, and runs to the supply grid for example.

Referring to FIG. 6, in one embodiment the hinge 29 comprises a bushing 31 and a pin 30. The pin 30 has two sections 30a and 30b that are mounted such that they are electrically insulated from one another by a cap 32. The separate connection of the two sections 30a, 30b is performed via the cables 16, 17.

Looking at the bushing 31 in FIG. 6 shows that the bushing 31 has two slip rings 35, 36 that are spring-mounted and arranged at a distance from one another and are each electrically connected to the cables 16, 17 and are mounted such that they are electrically insulated from the bushing itself. These slip rings 35, 36 are connected to the sections 30a, 30b of the pin 30. Given a sufficient length, the pin can be subdivided as often as desired by individual caps 32, wherein the bushing then has a corresponding number of slip rings 35, 36.

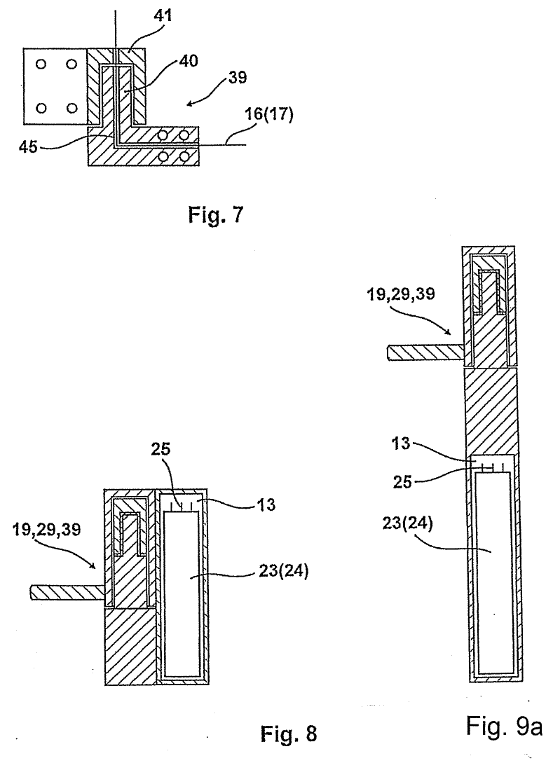

FIG. 7 shows a further embodiment of a hinge 39, wherein the hinge 39 again exhibits a bushing 41 and a pin 40. Both the pin 40 and the bushing 41 are provided, in the middle, with a hole 45 through which at least one cable 16, 17 is routed.

In the example embodiment illustrated in FIG. 8, the housing of the hinge 19, 29, 39 is increased in size to such an extent that it can hold a chamber 13 for holding an electrical or electronic component 24, possibly with a housing 23.

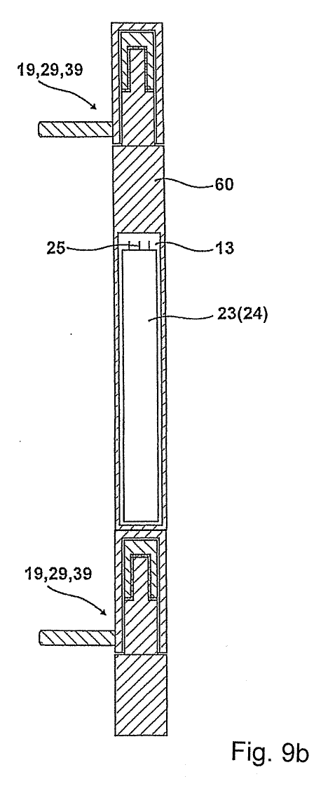

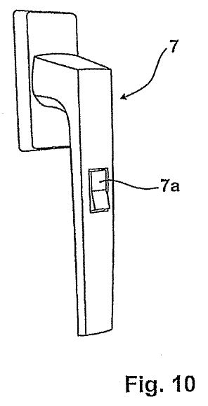

The same applies for the example embodiment that is illustrated in FIG. 9a where the housing of the hinge 19, 29, 39 is extended in the downward direction and likewise has a chamber 13 for holding a housing 23 of an electrical or electronic component 24.

The example embodiment shown in FIG. 9b corresponds substantially to that illustrated in FIG. 9a, wherein according to FIG. 9b, however, the two hinges 19, 29, 39 have a housing 60, which connects the two hinges and which once again exhibits a chamber 13 for holding a housing 23 of an electrical or electronic component.

The illustration according to FIG. 10 is an enlarged view of a handle 7 which has a switch 7a which is connected to an electrical or electronic component 24. For example, a photovoltaic system that comprises the at least one PV module 5 (cf. FIG. 1a) can be disconnected from the supply grid or connected to the supply grid by means of the switch.

1. A window or door for a building, wherein a glass element is surrounded by a frame or a fixed frame and comprises at least one PV module, wherein at least one electrical or electronic component for operating the at least one PV module is arranged in the frame or in the fixed frame.

2. The window or door as claimed in claim 1, wherein the frame is movably mounted in a fixed frame.

3. The window or door as claimed in claim 1, wherein the at least one electrical or electronic component comprises a module inverter, a submodule inverter, a DC/DC converter, an MPP tracker, a communication unit and/or an electrical energy storage component.

4. The window or door as claimed in claim 1, wherein the frame or the fixed frame comprises at least one chamber configured to hold the electrical or electronic component.

5. The window or door as claimed in claim 4, wherein the frame or the fixed frame is configured as a hollow profile in cross section that includes the at least one chamber.

6. The window or door as claimed in claim 4, wherein the at least one chamber is closed at one or both ends thereof.

7. The window or door as claimed in claim 6, further comprising a removable cover arranged at one or both ends of the at least one chamber of the frame or the fixed frame in order to close the at least one chamber.

8. The window or door as claimed in claim 4, wherein the electrical or electronic component comprises a housing that is configured to be inserted into the at least one chamber in the frame.

9. The window or door as claimed in claim 8, wherein the housing comprises outer faces, wherein the housing comprises cooling ribs on at least one of the outer faces.

10. The window or door as claimed in claim 4, wherein the component and/or the housing comprises a plug module, wherein a corresponding plug module is provided in the chamber, wherein the plug module and the corresponding plug module make contact with one another when the housing or the electrical or electronic component is inserted into the chamber.

11. The window or door as claimed in claim 2, wherein the frame is movably mounted in the fixed frame via a hinge, and wherein the hinge and/or a frame or fixed frame comprising metal are/is designed as an antenna in order to transmit data from and to a communication device of the electrical or electronic component.

12. The window or door as claimed in claim 1, further comprising a cutout or an inspection window associated with the frame or fixed frame for providing access to switching options or for reading off a display of the electrical or electronic component that is arranged in the frame or fixed frame in the region of the electrical or electronic component.

13. The window or door as claimed in claim 2, wherein the frame is movably mounted in the fixed frame via a hinge, and wherein the electrical energy that is generated by the PV module is conducted through the hinge that holds the window or door leaf on the fixed frame.

14. The window or door as claimed in claim 13, wherein the hinge comprises a pin and at least one bushing that are electroconductive.

15. The window or door as claimed in claim 14, wherein the pin is subdivided into at least two sections by at least one electrical insulation component.

16. The window or door as claimed in claim 15, wherein the electrical insulation component comprises a cap.

17. The window or door as claimed in claim 14, wherein the bushing comprises at least two electroconductive elements that are arranged in an electrically insulated manner in the bushing and that are connected to the electrical or electronic components and/or PV modules by cables.

18. The window or door as claimed in claim 17, wherein the at least one electroconductive element comprises a ring, slip ring, slip brush, spring contact or sleeve.

19. The window or door as claimed in claim 13, further comprising cables routed through the hinge and configured to transmit the electrical energy from the door or window frame to the fixed frame or a circumjacent masonry.

20. The window or door as claimed in claim 2, wherein the frame is movably mounted in the fixed frame via a hinge, and wherein the electrical or electronic component is integrated at least partially in a pin of the hinge.

21. The window or door as claimed in claim 2, wherein the frame is movably mounted in the fixed frame via a hinge, and wherein the electrical or electronic component is arranged at the hinge.

22. The window or door as claimed in claim 21, wherein the electrical or electronic component is arranged between two hinges.

23. The window or door as claimed in claim 1, wherein the frame comprises a handle, the handle comprising at least one switch that is connected to the electrical or electronic component.

24. The window or door as claimed in claim 23, wherein a switching process of the at least one switch is executed by pivoting the handle.

25. The window or door as claimed in claim 24, wherein a photovoltaic system which comprises the at least one PV module is configured to be disconnected from a supply grid by the switching process.
